(19) United States
(12) Patent Application Publication
(10) Pub. No.: US 2013/0285510 A1
(43) Pub. Date: Oct. 31, 2013

(54) METHOD FOR FABRICATING PIEZOELECTRIC COMPOSITE MATERIAL AND PIEZOELECTRIC POWER GENERATING DEVICE

(71) Applicants: Wu-Sung CHUANG, New Taipei City (TW); Chih-Chang Wei, New Taipei City (TW); Huey-Lin Hsieh, New Taipei City (TW); Cheng-Sheng Yu, New Taipei City (TW)

(72) Inventors: Wu-Sung CHUANG, New Taipei City (TW); Chih-Chang Wei, New Taipei City (TW); Huey-Lin Hsieh, New Taipei City (TW); Cheng-Sheng Yu, New Taipei City (TW)

(73) Assignee: BETACER INC.

(21) Appl. No.: 13/456,808

(22) Filed: Apr. 26, 2012

(51) Int. Cl. H02N 2/18; C04B 35/64; H01L 41/18

(52) U.S. Cl. 310/339; 264/614

(57) ABSTRACT

The invention relates to a method for fabricating piezoelectric composite material comprising steps of mixing a piezoelectric ceramic powder, an adhesive, a cross-linking agent, a lubricant and a plasticizer to form a slurry; extruding the slurry to form a piezoelectric ceramic green fiber; sintering the piezoelectric ceramic green fiber to form the piezoelectric ceramic fiber; arranging the piezoelectric ceramic fiber in a mold according to a predetermined volumetric content; and adding a polymer into the mode to form a polymer matrix of piezoelectric composite material. A piezoelectric power generating device including a piezoelectric power generating element made of the piezoelectric composite material is also provided.

### BACKGROUND OF THE INVENTION

1. Field of the Invention

This invention generally relates to piezoelectric composite material, and in particular to a method for manufacturing piezoelectric composite material.

2. Description of Related Art

The traditional piezoelectric material is typically in bulk form, and is rigid and fragile, so that there is a limitation of electromechanical conversion output of the traditional piezoelectric material and cannot be easily applied in various applications. However, the piezoelectric composite material has excellent piezoelectric property of piezoelectric ceramics and flexibility of polymer, and thus can enhance piezoelectric property and mechanical property for using widely in various fields.

There are several kinds of method for manufacturing piezoelectric composite material such as laser cutting-filling, injection molding, ejection molding and piezoelectric ceramics fiber arrangement casting. The laser cutting-filling may first form multiple pillars by using laser ray to cut multiple lateral grooves and multiple longitudinal grooves that cross over the lateral grooves on a piezoelectric ceramics bulk, and then fill polymer in the grooves to form piezoelectric composite material. Compared to diamond knife cutting-filling, the laser cutting-filling is provided with several advantages of high preciseness, without contact and easy manipulation. However, the method has the disadvantages that the equipment cost is high and heat produced from the laser ray may fracture ceramics material and affect the structure and property of material.

The injection molding may first form piezoelectric ceramics pillars array by using a syringe with multiple tubular outlets on a piezoelectric ceramics bulk, and proceed sintering, and then fill polymer in the array to form piezoelectric composite material. The injection molding is provided with an advantage of flexible control of size, distribution and volume content of piezoelectric ceramics pillars. However, the method has the disadvantages that the structure of the syringe is complicated and the length of the piezoelectric ceramics pillar is limited.

The ejection molding may first eject to form piezoelectric ceramics pillars array by using a mold having multiple pillar recesses on a piezoelectric ceramics bulk, and proceed sintering, and then fill polymer in the array to form piezoelectric composite material. The ejection molding is provided with advantages that the mold is easy to manufacture and has low price. However, the method has the disadvantages that the thermal stress of sintering is easy to collapse the piezoelectric ceramics pillars as the diameter of the piezoelectric ceramics pillar is below 100 microns.

The piezoelectric ceramics fiber arrangement casting first have to manufacture piezoelectric ceramics fibers, and provide and arrange the piezoelectric ceramics fibers in a mold according to a predetermined volume content, and provide a polymer, for example epoxy, in the mold to imbed the piezoelectric ceramics fibers. An type 1-3 piezoelectric composite material is obtained after curing and ejecting. The piezoelectric ceramics fiber arrangement casting has advantages that the method is a simple process, fiber volume content is easy to control and air pore rate is low. Therefore, the method is suitable for making sensors with high performance and drivers, and so on.

Currently, several manufacturing methods of piezoelectric ceramic fibers have been proposed, for example sol-gel method, VSSP and extruding method. In the extruding method, a piezoelectric ceramic powder, an adhesive and a cross-linking agent are mixed to form a polymer sol. The polymer sol is extruded into a piezoelectric ceramic green fiber by an extruder. The piezoelectric ceramic green fiber is dried and sintered to form a piezoelectric ceramic fiber. Although the method is simple, low cost and no environmental pollution, the piezoelectric ceramic fiber cannot smoothly extrude and has poor plasticity.

Further, the type 1-3 piezoelectric composite material comprises two phases, a one-directional communicating piezoelectric ceramic fibers phase parallel imbedding in a three-directional communicating polymer matrix phase. The power of piezoelectric power generating device can be raised by increasing the size of piezoelectric power generating element. There is a need for a piezoelectric power generating element that can produce high power and the element does not cause cracks on the surface after vibrating for a long time.

Therefore, the inventor conducted researches according to the scientific approach in order to improve and resolve the above drawback, and finally proposed the present invention, which is reasonable and effective.

### SUMMARY OF THE INVENTION

An object of the invention is to provide a method for fabricating piezoelectric composite material. The method can smoothly extrude the piezoelectric ceramic fibers that have excellent plasticity. Also, the invention provides a piezoelectric composite material to manufacture a piezoelectric power generating element that can produce high power and the element does not cause cracks on the surface after vibrating for a long time.

Another object of the invention is to provide a piezoelectric power generating device comprising a piezoelectric power generating element made from the piezoelectric composite material.

In order to achieve the above object, there is provided a method for fabricating piezoelectric composite material comprising steps of mixing a piezoelectric ceramic powder, an adhesive, a cross-linking agent, a lubricant and a plasticizer to form a slurry; extruding the slurry to form a piezoelectric ceramic green fiber; sintering the piezoelectric ceramic green fiber to form the piezoelectric ceramic fiber; arranging the piezoelectric ceramic fiber in a mold according to a predetermined volumetric content; and adding a polymer into the mode to form a polymer matrix of piezoelectric composite material.

Also, the invention relates to a piezoelectric power generating device including a supporting part; a metal plate having a first surface and a second surface opposite each other, the metal plate having an end fixed in the supporting part; and at least one piezoelectric power generating element adjacent to the first surface and/or the second surface, the piezoelectric power generating element made of the piezoelectric composite material.

Compared with the prior arts, the invention provides the method can smoothly extrude the piezoelectric ceramic fibers that have excellent plasticity by adding the lubricant and the plasticizer. Also, the invention provides a piezoelectric composite material with suitable ratio of two phases to manufacture a piezoelectric power generating element that can produce high power and the element does not cause cracks on the surface after vibrating for a long time. The piezoelectric power generating element can be used in manufacturing a piezoelectric power generating device. Advantageously, the method is a simple, low cost process with no pollutions. The method may be applied in the manufacture of thin and long piezoelectric power generating element.

### BRIEF DESCRIPTION OF THE DRAWINGS

FIG. 1 shows a flow diagram of manufacturing steps of piezoelectric composite material of a preferred embodiment according to the present invention.

FIG. 2 shows a schematic view of a first embodiment of a piezoelectric power generating device according to the present invention.

FIG. 3 shows a schematic view of a second embodiment of a piezoelectric power generating device according to the present invention.

FIG. 4 shows a schematic view of a third embodiment of a piezoelectric power generating device according to the present invention.

FIG. 5 shows a schematic view of a fourth embodiment of a piezoelectric power generating device according to the present invention.

### DETAILED DESCRIPTION OF THE INVENTION

The technical content of invention will be explained in more detail below with reference to a few figures. However, the figures are intended solely for illustration and not to limit the inventive concept.

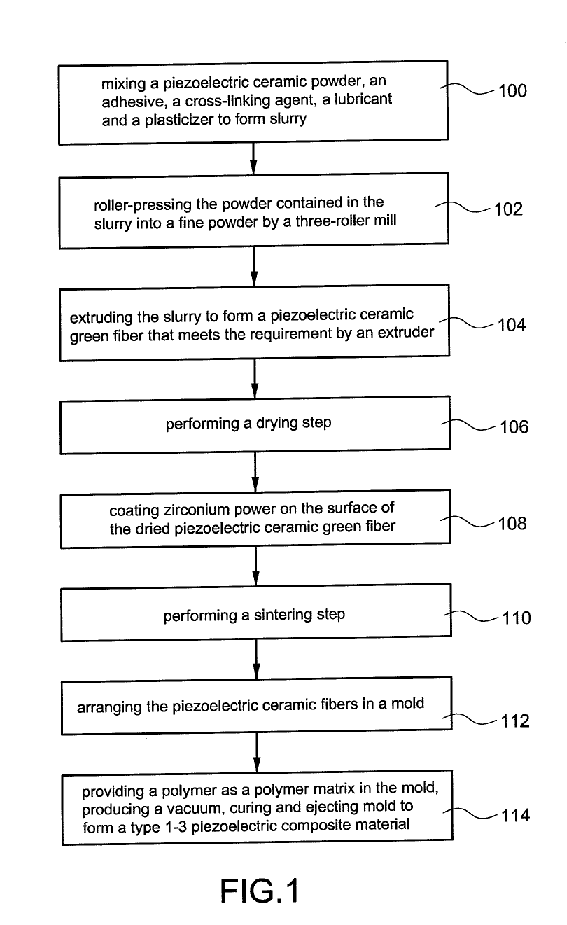

Please refer to FIG.1 which shows a flow diagram of manufacturing steps of piezoelectric ceramic fibers according to a preferred embodiment of the present invention. First, referring to step 100 in FIG.1, a piezoelectric ceramic powder in an amount of 70 wt %-95 wt %, an adhesive in an amount of 3.5˜20 wt %, a cross-linking agent in an amount of 0.5˜5 wt %, a lubricant in an amount of 0.5˜2.5 wt % and a plasticizer in an amount of 0.5˜2.5 wt % are mixed to form slurry by a blender.

The piezoelectric ceramic powder may be expressed by ABO3, wherein A is Pb, Ba, La, Sr, K, or Li, and B is Ti, Zr, Mn, Co, Nb, Fe, Zn, Mg, Y, Sn, Ni, or W. In an embodiment of the present invention, a particle size of the piezoelectric ceramic powder is between 0.1 and 1.0 μm and the piezoelectric ceramic powder is in an amount of 70 wt %-95 wt %.

In an embodiment of the present invention, a suitable adhesive may be methyl cellulose group, for example methyl cellulose or hydroxypropyl methyl cellulose; poly vinyl alcohol group, for example poly vinyl alcohol, poly vinyl acetate; and poly acrylate. The adhesive is in an amount of 3.5˜20 wt %.

In an embodiment of the present invention, a cross-linking agent may be a solution comprising boric acid, borate, phosphate, silicate or aluminate. The borate may be sodium borate or potassium borate. The phosphate may be sodium phosphate, potassium phosphate or manganese phosphate. The silicate may be sodium silicate, potassium silicate or aluminum silicate. The aluminate may be sodium aluminate or potassium aluminate. The cross-linking agent may be an aqueous solution in a concentration between 0.005 and 0.05 M. The cross-linking agent is in an amount of 0.5˜5 wt %. The cross-linking agent may produce alkali hydroxides with charges as it is dissolved in water, and the hydroxides may cross-link with the adhesive to form a three dimensional network containing the ceramic powder. A compact composite structure with three dimensional network may be form after a spontaneous dehydration reaction.

In an embodiment of the present invention, the suitable lubricant is glycerol or dipropylene glycol. The lubricant is in an amount of 0.5˜2.5 wt %. It can facilitate extrusion by adding a proper amount of lubricant and prevent from sticking on the inner wall and holes of the extruder.

In an embodiment of the present invention, the plasticizer may be selected from the group consisting of polyvinyl ethylene glycol, 1,3-butanediol, 1,4-butanediol and benzyl alcohol. The plasticizer is in an amount of 0.5˜2.5 wt %. It can improve plasticity of the fibers to meet the requirement by adding a proper amount of plasticizer.

Next, referring to step 102 in FIG. 1, the powder contained in the slurry is roller-pressed into a fine powder by a three-roller mill. Then, referring to step 104 in FIG. 1, the slurry is extruded to form a piezoelectric ceramic green fiber that meets the requirement by an extruder. The pressure for extruding the slurry is, for example, between 1 and 50 kg/cm2. The diameter of the piezoelectric ceramic green fiber is, for example, between 75 and 1000 μm.

Next, referring to step 106 in FIG. 1, the piezoelectric ceramic green fiber is dried in an oven to remove moisture contained in the piezoelectric ceramic green fiber. The temperature of the drying step is, for example, between 80 and 120° C.

Next, referring to step 108 in FIG. 1, zirconium power is coated on the surface of the dried piezoelectric ceramic green fiber to enhance surface abrasion resistance of fibers. The piezoelectric ceramic green fiber is disposed on an alumina substrate in a crucible.

Next, referring to step 110 in FIG. 1, the piezoelectric ceramic green fiber disposed in the crucible is sintered into the fiber product in a sintering oven. In the embodiment, the temperature of the sintering step is, for example between 1,000 and 1,300° C.

After determining, the piezoelectric ceramic fiber has a diameter of 250 microns, a length from 70 to 100 mm, roundness tolerance of 0.07+0.001 microns/mm, straightness tolerance of 0.25 microns/100 mm, sintering density larger than 99% and the piezoelectric strain coefficient d33 larger than 600 p C/N.

Next, referring to step 112 in FIG. 1, the piezoelectric ceramic fiber is arranged in a mold according to a volumetric content of 35%˜85%. The piezoelectric strain coefficient is high in proportion to the volumetric content of the piezoelectric ceramic fiber to the piezoelectric composite material. Also, the arrangement, for example periodic arrangement and non-periodic arrangement of piezoelectric ceramic fibers provided in the piezoelectric composite material may affect thickness resonating mode of piezoelectric element. The piezoelectric ceramic fibers with non-periodic arrangement simplify the thickness resonating mode without affecting the other property.

Next, referring to step 114 in FIG. 1, a polymer as a polymer matrix is provided in the mold, producing a vacuum from 30 to 40 minutes, curing from 6 to 9 hours at temperature of 160˜180° C. and ejecting mold to form a type 1-3 piezoelectric composite material. The suitable polymer may be epoxy and silicone. The method for manufacturing epoxy polymer including steps of selecting an epoxy as a substrate, adding curing agent, for example maleic anhydride or hexahydrophthalic anhydride into the substrate with weight ratio 3:1 of the substrate: the curing agent. The diluent, for example dioctyl phthalate may be added to dilute epoxy if need. The usage amount of the diluent may be 1 wt. % of epoxy.

The piezoelectric composite material is sliced into a sheet with 2 mm of thickness for determining the property of the piezoelectric composite material. The sheet is polished and then coated with silver electrode. The sheet is polarized under dielectric strength of 1.5˜2.5 kV/mm, temperature of 100° C. and from about 15 minutes to about 25 minutes in silicone oil. The d33 of the piezoelectric composite material is larger than 300 pC/N.

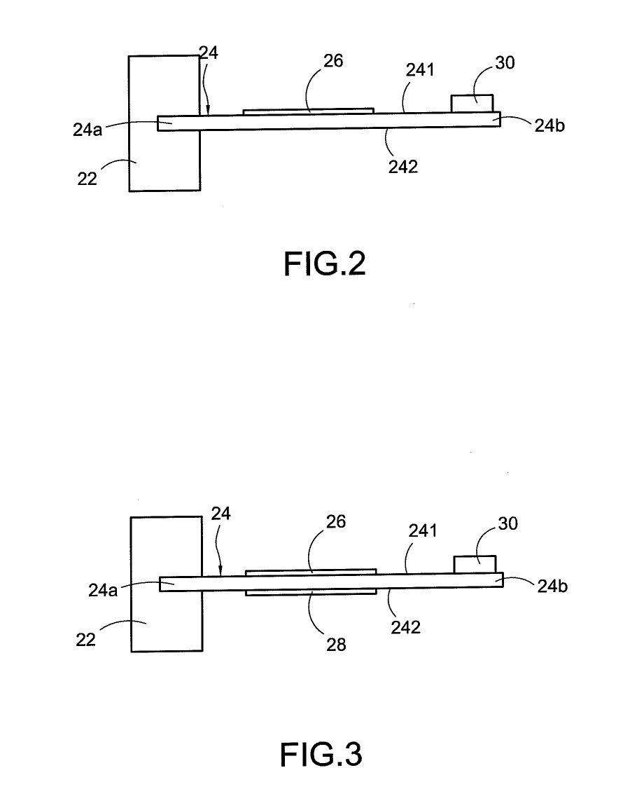

Next, please refer to FIG. 2. FIG. 2 shows a schematic view of a first embodiment of a piezoelectric power generating device according to the present invention. The invention provides a piezoelectric power generating device 20 comprising a supporting part 22, a metal plate 24 and a piezoelectric power generating element 26. The metal plate 24 has a first surface 241 and a second surface 242 opposite each other. The metal plate 24 has an end 24a fixed in the supporting part 22. The piezoelectric power generating element 26 is adjacent to the first surface 241. The piezoelectric power generating element 26 is made of the piezoelectric composite material of the invention. The piezoelectric power generating element 26 has a plate-like shape, having a length from 3 to 10 cm, 10 cm is preferred and thickness may be from 30 microns to 3 mm. Further, a weight 30 can be mounted to a free end 24b of the first surface 241 of the metal plate 24 to facilitate the vibration of the piezoelectric power generating element 26. The weight 30 has mass from 0.5 grams to 10 grams.

Next, please refer to FIG. 3. FIG. 3 shows a schematic view of a second embodiment of a piezoelectric power generating device according to the present invention. The invention provides a piezoelectric power generating device 20 comprising a supporting part 22, a metal plate 24 and two piezoelectric power generating elements 26, 28. The metal plate 24 has a first surface 241 and a second surface 242 opposite each other. The piezoelectric power generating element 26 is adjacent to the first surface 241, and piezoelectric power generating element 28 is adjacent to the second surface 242. The piezoelectric power generating elements 26, 28 are made of the piezoelectric composite material of the invention. The piezoelectric power generating elements 26, 28 have a plate-like shape, having a length from 3 to 10 cm, 10 cm is preferred and thickness may be from 30 microns to 3 mm. Further, a weight 30 can be mounted to a free end 24b of the first surface 241 of the metal plate 24 to facilitate the vibration of the piezoelectric power generating elements 26, 28.

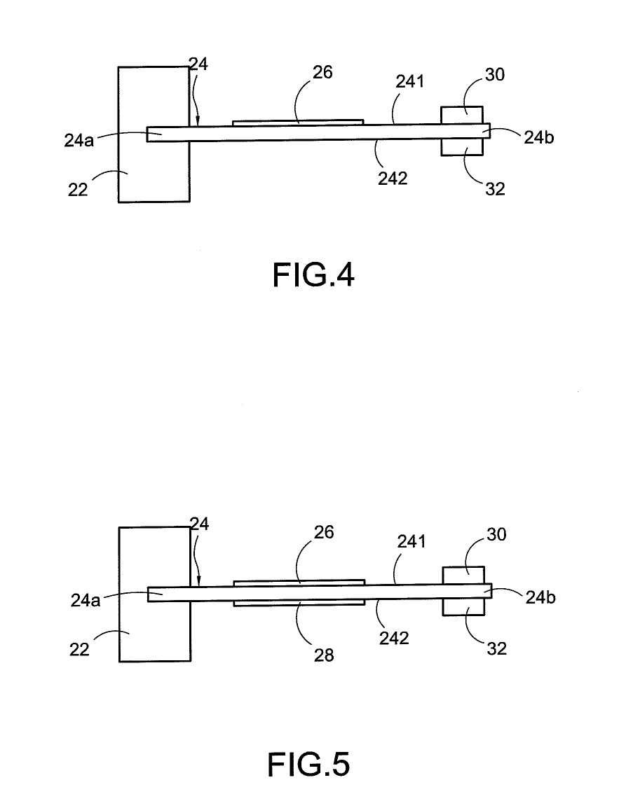

Next, please refer to FIG. 4. FIG. 4 shows a schematic view of a third embodiment of a piezoelectric power generating device according to the present invention. The invention provides a piezoelectric power generating device 20 comprising a supporting part 22, a metal plate 24 and a piezoelectric power generating element 26. The metal plate 24 has a first surface 241 and a second surface 242 opposite each other. The metal plate 24 has an end 24a fixed in the supporting part 22. The piezoelectric power generating element 26 is adjacent to the first surface 241. The piezoelectric power generating element 26 is made of the piezoelectric composite material of the invention. The piezoelectric power generating element 26 has a plate-like shape, having a length from 3 to 10 cm, 10 cm is preferred and thickness may be from 30 microns to 3 mm. Further, two weights 30, 32 can be mounted to a free end 24b of the first surface 241 and the second surface 242 of the metal plate 24 to facilitate the vibration of the piezoelectric power generating element 26.

Next, please refer to FIG. 5. FIG. 5 shows a schematic view of a fourth embodiment of a piezoelectric power generating device according to the present invention. The invention provides a piezoelectric power generating device 20 comprising a supporting part 22, a metal plate 24 and two piezoelectric power generating elements 26, 28. The metal plate 24 has a first surface 241 and a second surface 242 opposite each other. The piezoelectric power generating element 26 is adjacent to the first surface 241, and piezoelectric power generating element 28 is adjacent to the second surface 242. The piezoelectric power generating elements 26, 28 are made of the piezoelectric composite material of the invention. The piezoelectric power generating elements 26, 28 have a plate-like shape, having a length from 3 to 10 cm, 10 cm is preferred and thickness may be from 30 microns to 3 mm. Further, two weights 30, 32 can be mounted to a free end 24b of the first surface 241 and the second surface 242 of the metal plate 24 to facilitate the vibration of the piezoelectric power generating element 26, 28.

The invention is not limited to these embodiments, but various variations and modifications may be made without departing from the scope of the invention.

What is claimed is:

1. A method for fabricating piezoelectric composite material comprising steps of :
(a) mixing a piezoelectric ceramic powder, an adhesive, a cross-linking agent, a lubricant and a plasticizer to form a slurry;
(b) extruding the slurry to form a piezoelectric ceramic green fiber;
(c) sintering the piezoelectric ceramic green fiber to form the piezoelectric ceramic fiber;
(d) arranging the piezoelectric ceramic fiber in a mold according to a predetermined volumetric content; and
(e) adding a polymer as a polymer matrix into the mode to form a piezoelectric composite material.

2. The method for fabricating piezoelectric composite material as claimed in claim 1, wherein in the step (a), the lubricant is glycerol or dipropylene glycol, and the amount of the lubricant is 0.5˜2.5 wt %.

3. The method for fabricating piezoelectric composite material as claimed in claim 1, wherein in the step (a), the plasticizer is selected from the group consisting of polyvinyl ethylene glycol, 1,3-butanediol, 1,4-butanediol and benzyl alcohol, and the amount of the plasticizer is 0.5˜2.5 wt %.

4. The method for fabricating piezoelectric composite material as claimed in claim 1, wherein in the step (a), the piezoelectric ceramic powder is expressed by ABO3, wherein A is Pb, Ba, La, Sr, K, or Li, and B is Ti, Zr, Mn, Co, Nb, Fe, Zn, Mg, Y, Sn, Ni, or W, and the amount of the piezoelectric ceramic powder is 70 wt %-95 wt %.

5. The method for fabricating piezoelectric composite material as claimed in claim 1, wherein in the step (a), wherein a particle size of the piezoelectric ceramic powder is between 0.1 and 1.0 μm.

6. The method for fabricating piezoelectric composite material as claimed in claim 1, wherein in the step (a), wherein the adhesive is methyl cellulose or hydroxypropyl methyl cellulose, and the amount of the adhesive is 3.5˜20 wt %.

7. The method for fabricating piezoelectric composite material as claimed in claim 1, wherein in the step (a), the cross-linking agent is a solution comprising boric acid, borate, phosphate, silicate or aluminate, and the cross-linking agent is an aqueous solution in a concentration between 0.005 and 0.05 M.

8. The method for fabricating piezoelectric composite material as claimed in claim 7, wherein in the step (a), the cross-linking agent is in an amount of 0.5˜5 wt %.

9. The method for fabricating piezoelectric composite material as claimed in claim 1, wherein in the step (b), the pressure for extruding the slurry is between 1 and 50 kg/cm2.

10. The method for fabricating piezoelectric composite material as claimed in claim 1, wherein in the step (b), the diameter of the piezoelectric ceramic green fiber is between 75 and 1,000 μm.

11. The method for fabricating piezoelectric composite material as claimed in claim 1, wherein in the step (c), the temperature of the sintering step is between 1,000 and 1,300° C.

12. The method for fabricating piezoelectric composite material as claimed in claim 1, further comprising a drying step before the step (c), and the temperature of the drying step is between 80 and 120° C.

13. The method for fabricating piezoelectric composite material as claimed in claim 1, wherein in the step (d), the volumetric content is between 35% and 85%.

14. The method for fabricating piezoelectric composite material as claimed in claim 1, wherein in the step (e), the polymer is epoxy or silicone.

15. A piezoelectric power generating device comprising:
a supporting part;
a metal plate having a first surface and a second surface opposite each other, the metal plate having an end fixed in the supporting part; and
at least one piezoelectric power generating element adjacent to the first surface and/or the second surface, the piezoelectric power generating element made of the piezoelectric composite material as claimed in claim 1.

16. The piezoelectric power generating device as claimed in claim 15, wherein two piezoelectric power generating elements are respectively adjacent to the first surface and the second surface of the metal plate.

17. The piezoelectric power generating device as claimed in claim 15, further comprising a weight is mounted to a free end of the metal plate, or two weights are mounted to the first surface and the second surface of the free end of the metal plate.

18. The piezoelectric power generating device as claimed in claim 16, further comprising a weight is mounted to a free end of the metal plate, or two weights are mounted to the first surface and the second surface of the free end of the metal plate.

19. The piezoelectric power generating device as claimed in claim 15, wherein the piezoelectric power generating element has a plate-like shape, and has a length between 3 cm and 10 cm.

20. The piezoelectric power generating device as claimed in claim 15, wherein the piezoelectric power generating element has a thickness between 30 microns and 3 mm.
